(19) United States
(12) Patent Application Publication
(10) Pub. No.: US 2026/0038584 A1
(43) Pub. Date: Feb. 5, 2026

(54) APPARATUSES, SYSTEMS AND METHODS FOR CONTROLLING VARIABLE GAIN AMPLIFIERS

(71) Applicant: Micron Technology, Inc., Boise, ID (US)

(72) Inventors: Hyun Yoo Lee, Boise, ID (US); SeungWook Oh, Boise, ID (US); Jinha Hwang, Boise, ID (US)

(73) Assignee: Micron Technology, Inc., Boise, ID (US)

(21) Appl. No.: 19/281,276

(22) Filed: Jul. 25, 2025

Related U.S. Application Data
(60) Provisional application No. 63/677,839, filed on Jul. 31, 2024.

(51) Int. Cl. G11C 11/4096; H03F 1/02; H03G 3/30; H03K 3/037

(52) U.S. Cl. CPC G11C 11/4096; H03F 1/0205; H03G 3/30; H03K 3/037; H03G 2201/103

(57) ABSTRACT

A variable gain amplifier (VGA) includes a sink circuit. One or more control signals are provided to the sink circuit to selectively enable sink transistors in the sink circuit. The control signals can be staggered in time to reduce power consumption of the VGA.

### CROSS-REFERENCE TO RELATED APPLICATIONS

This application claims the filing benefit of U.S. Provisional Application No. 63/677,839, filed Jul. 31, 2024. This application is incorporated by reference herein in its entirety and for all purposes.

### BACKGROUND

A semiconductor memory device may include a number of memory cells which are used to store data represented by binary digits (or “bits”). The memory cells are typically arranged in an array and are accessed based on row addresses and column addresses. When write operations are performed, data is written to memory cells based on write commands supplied with row and column addresses that are used to select the memory cells. Prior to writing the data to the memory cells, the data signals are amplified by one or more variable gain amplifiers (VGAs). Typically, a VGA consumes a large amount of power, which is undesirable. Additionally, as the number of memory devices that are included in a system continues to increase, the total system power has to increase to compensate for the large amounts of power consumed by the increasing number of VGAs.

### BRIEF DESCRIPTION OF THE DRAWINGS

Non-limiting and non-exhaustive examples are described with reference to the following Figures. The elements of the drawings are not necessarily to scale relative to each other. Identical reference numerals have been used, where possible, to designate identical features that are common to the Figures.

FIG. 1 illustrates a block diagram of an example semiconductor device according to an embodiment of the disclosure;

FIG. 2 illustrates an example process flow diagram for a write command according to an embodiment of the disclosure;

FIG. 3 illustrates a block diagram of an example shifter and pulse generator circuit according to an embodiment of the disclosure;

FIG. 4 illustrates an example waveform of the pre-write enable signal WrEnIBdetPre shown in FIG. 2 and FIG. 3 according to an embodiment of the disclosure;

FIG. 5 illustrates a block diagram of a first example delay control circuit according to an embodiment of the disclosure;

FIG. 6 illustrates an example timing diagram for the delay control circuit shown in FIG. 5 according to an embodiment of the disclosure;

FIG. 7 illustrates a block diagram of an example set pulse generator with example waveform diagrams according to an embodiment of the disclosure;

FIG. 8 illustrates a block diagram of an example reset pulse generator with example waveform diagrams according to an embodiment of the disclosure according to an embodiment of the disclosure;

FIGS. 9A-9E illustrate example operations of a variable gain amplifier control circuit according to an embodiment of the disclosure according to an embodiment of the disclosure;

FIG. 10 illustrates a first example timing diagram for a variable gain amplifier power savings according to an embodiment of the disclosure;

FIG. 11 illustrates a block diagram of a second example delay control circuit according to an embodiment of the disclosure;

FIG. 12 illustrates an example timing diagram for the delay control circuit shown in FIG. 11 according to an embodiment of the disclosure; and

FIG. 13 illustrates a second example timing diagram for a variable gain amplifier power savings according to an embodiment of the disclosure.

### DETAILED DESCRIPTION

Semiconductor memory devices typically include one or more variable gain amplifiers (VGAs) to amplify data signals prior to the data being written into a memory array. In some instances, all of the sink transistors in a VGA are enabled (e.g., turned on) at the same time and for the same time period, which can result in a higher amount of power consumption by each VGA, a greater settling time for the VGA, and/or greater power fluctuations in the memory device.

Embodiments described herein provide techniques for controlling one or more VGAs. One or more control signals are provided to a sink circuit in a VGA to selectively enable sink transistors in the sink circuit. The sink circuit can be used to set one or more settings of the VGA, such as the gain and/or the bandwidth of the VGA. For example, when more sink transistors and/or stronger sink transistors are enabled, the VGA can have a relatively higher gain. Conversely, when fewer sink transistors and/or weaker sink transistors are enabled, the VGA may have a relatively lower gain.

The control signals can be staggered in time to reduce the power consumption of the VGA. As such, the control signal received at one sink transistor can be enabled (e.g., an assertion transition time) at a first time and the control signal received at another sink transistor may be enabled at a later second time. In one embodiment, the weaker sink transistors are enabled first and the stronger sink transistors later. Enabling the weaker sink transistors first can assist in satisfying a settling time of the VGA. Additionally or alternatively, enabling the weaker sink transistors first and the stronger sink transistors later may reduce or minimize the amount of time the stronger sink transistors are enabled, which can further reduce the power consumption of the VGA.

The control signals can be disabled (e.g., a deassertion transition time) at the same time in one embodiment. In another embodiment, the control signal received at one sink transistor may be disabled before the control signal received at another sink transistor is disabled. The staggered disabling of the control signals may reduce power fluctuations. In some aspects, enable signals that are provided to the VGA may be delayed to further reduce the power consumption of the VGA.

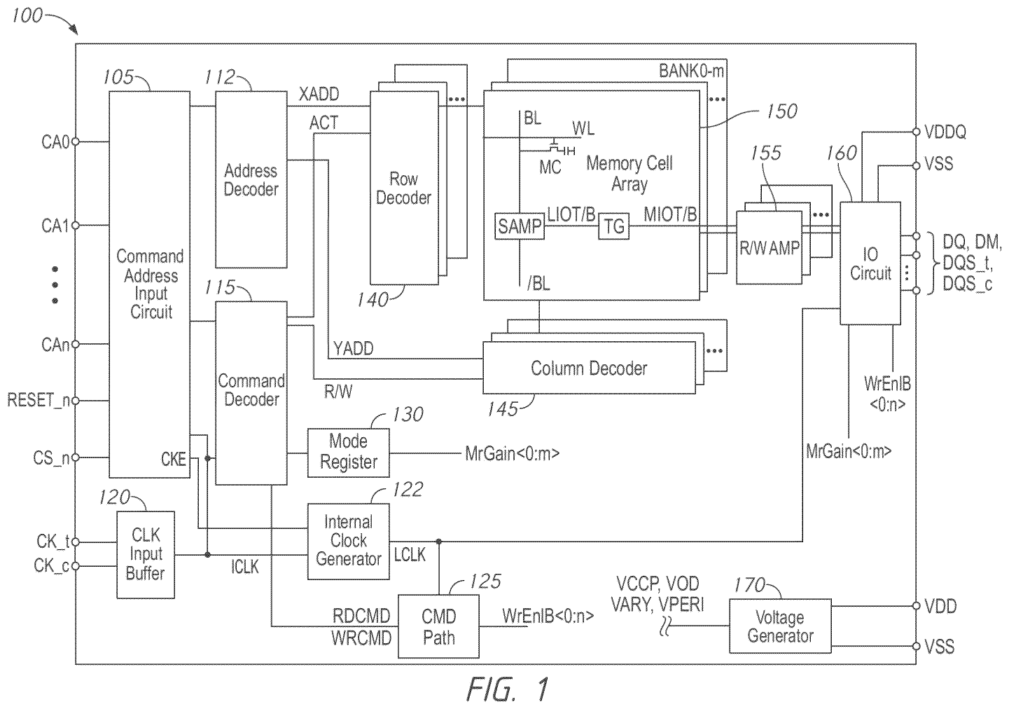

FIG. 1 illustrates a block diagram of a semiconductor device 100 according to an embodiment of the disclosure. The semiconductor device 100 may include, without limitation, a dynamic random-access memory (DRAM), a double data rate (DDR) memory, a low power double data rate (LPDDR) memory, or other type of memory. In some instances, the memory is included in a memory module, such as a single in-line memory module, a dual in-line memory module, a quad in-line memory module, or another type of memory module.

The semiconductor device 100 includes a memory array 150. The memory array 150 is shown as including a plurality of memory banks. In the embodiment of FIG. 1, the memory array 150 is shown as including memory banks BANKO-BANKm. Each memory bank includes a plurality of word lines WL, a plurality of bit lines BL and/BL, and a plurality of memory cells MC arranged at intersections of the plurality of word lines WL and the plurality of bit lines BL and/BL. Selection of the word line WL is performed by a row decoder 140 and selection of the bit lines BL and/BL is performed by a column decoder 145. In the illustrated embodiment, the row decoder 140 includes a respective row decoder for each memory bank and the column decoder 145 includes a respective column decoder for each memory bank. The bit lines BL and/BL are coupled to a respective sense amplifier (SAMP). Read data from the bit line BL or/BL is amplified by the sense amplifier SAMP and transferred to read/write amplifiers 155 over complementary local data lines (LIOT/B), transfer gate (TG), and complementary main data lines (MIOT/B). Conversely, write data output from the read/write amplifiers 155 is transferred to the sense amplifier SAMP over the complementary main data lines MIOT/B, the transfer gate TG, and the complementary local data lines LIOT/B, and written in the memory cell MC coupled to the bit line BL or/BL.

A mode register 130 stores information, for example, configuration and status information for the semiconductor device 100. The mode register 130 may be accessed through mode register read commands and mode register write commands. The mode register access commands cause the semiconductor device 100 to perform mode register read operations and mode register write operations. A mode register read command causes the semiconductor device 100 to provide information stored by the mode register that is accessed, and a mode register write command causes the semiconductor device 100 to store information in the mode register that is accessed. The mode register 130 may include several mode registers, with each of the mode registers corresponding to a mode register address and storing different types of information.

The semiconductor device 100 may employ a plurality of external terminals that include command and address terminals (CAO-CAn) to receive commands and addresses, an external reset_n signal and an external control CS_n signal. The external terminals may further include clock terminals to receive clocks CK_t and CK_c, and data clocks DQS_t and DQS_c, data terminals DQ, and power supply terminals to receive power supply potentials VDD, VSS, and VDDQ.

The clock terminals are supplied with external clocks CK_t and CK_c that are provided to a CLK input buffer 120. The external clocks may be complementary (e.g., 180 degrees out of phase). The CLK input buffer 120 generates an internal clock ICLK based on the CK_t and CK_c clocks. The ICLK clock is provided to a command decoder 115, a command/address input circuit 105, and to an internal clock generator 122. The internal clock generator 122 provides various internal clocks LCLK based on the ICLK clock. The LCLK clocks may be used for timing operation of various internal circuits.

The power supply terminals are supplied with power supply potentials VDD and VSS. The power supply potentials VDD and VSS are supplied to an internal voltage generator circuit 170. The internal voltage generator circuit 170 generates various internal potentials VCCP, VOD, VARY, VPERI, and the like based on the power supply potentials VDD and VSS supplied to the power supply terminals. The internal potential VCCP is mainly used in the row decoder 140, the internal potentials VOD and VARY are mainly used in the sense amplifiers SAMP included in the memory array 150, and the internal potential VPERI is used in many peripheral circuit blocks.

The power supply terminals are also supplied with power supply potentials VDDQ and VSS. The power supply potentials VDDQ and VSS are supplied to the input/output circuit 160. The power supply potentials VDDQ and VSS supplied to the power supply terminals may be the same potentials as the power supply potentials VDD and VSS supplied to the power supply terminals in an embodiment of the disclosure. The power supply potentials VDDQ and VSS supplied to the power supply terminals may be different potentials from the power supply potentials VDD and VSS supplied to the power supply terminals in another embodiment of the disclosure. The power supply potentials VDDQ and VSS supplied to the power supply terminals are used for the input/output circuit 160 so that power supply noise generated by the input/output circuit 160 does not propagate to the other circuit blocks.

The CA terminals (e.g., CAO-CAn) may be supplied with commands and memory addresses from, for example, a memory controller. The memory addresses supplied to the CA terminals are transferred to an address decoder 112 via the command/address input circuit 105. The address decoder 112 receives the address and supplies a decoded row address XADD to the row decoder 140 and supplies a decoded column address YADD to the column decoder 145.

The commands received at the CA terminals may be provided as internal command signals to the command decoder 115 via the command/address input circuit 105. Example commands that may be received at the CA terminals include access commands for accessing the memory (such as read commands for performing read operations and write commands for performing write operations), mode register write and read commands for performing mode register write and read operations, power down commands, as well as other commands and operations.

The command decoder 115 includes circuits to decode the command signals to generate various internal command signals for performing operations. For example, the command decoder 115 may generate a row command signal ACT to select a word line, a column command signal R/W to select a bit line, a read command signal RDCMD based on a read command, and a write command signal WRCMD based on a write command.

The various internal command signals, such as the WRCMD signal, are provided to a command path 125. The command path 125 may include some or all of a write command path that receives the WRCMD signals and provides write enable signals WrEnIB<n>. The WrEnIB<n> signals are provided to the input/output circuit 160 to perform operations related to the write commands, such as providing amplified write data to the memory array 150.

Read data is read from a memory cell in the memory array 150 corresponding to a row address and a column address when an activate command and read command are received, and the row address and the column address are timely supplied with the activate command and/or the read command. The read command is received by the command decoder 115, which provides internal commands so that read data from the memory array 150 is provided to the read/write amplifiers 155. The read data is output to outside from the data terminals DQ via the input/output circuit 160. The DQS_t and DQS_c clocks are provided externally from clock terminals for timing the provision of the read data by the input/output circuit 160. The external terminals DQ include several separate terminals, each providing a bit of data synchronized with a clock edge of the DQS_t and DQS_c clocks.

Write data supplied to the data terminals DQ is written to a memory cell in the memory array 150 corresponding to a row address and a column address when an activate and write command are received, and the row address and the column address are timely supplied with the activate command and/or the write command. A data mask may be provided to the data terminals DM to mask portions of the data when written to the memory array 150. The write command is received by the command decoder 115, which provides internal commands so that the write data is received by input receivers in the input/output circuit 160. DQS_t and DQS_c clocks are also provided to the external clock terminals (e.g., by a controller) for timing the receipt of the write data by the input receivers of the input/output circuit 160. The write data is supplied via the input/output circuit 160 to the read/write amplifiers 155, and by the read/write amplifiers 155 to the memory array 150 to be written into the memory cell MC. As previously described, the external terminals DQ include several separate terminals. With reference to a write operation, each external terminal DQ concurrently receives a bit of data synchronized with a clock edge of the DQS_t and DQS_c clocks.

When a mode register read command is received, and a mode register address is timely supplied with the mode register read command, read information is read from the mode register 130 corresponding to the mode register address. The read information may be used to configure the semiconductor device 100, or the read information can be output to outside from the data terminals DQ via the input/output circuit 160. When a mode register write command is received, and a mode register address is timely supplied with the mode register write command, write information supplied to the data terminals DQ is written to the mode register 130 corresponding to the mode register address. In some instances, the mode register 130 stores gain information MrGain<0: m> that is provided to one or more variable gain amplifiers in the input/output circuit 160 during a write operation to the memory array 150. The gain information MrGain<0: m> can be set by an external device, such as a controller.

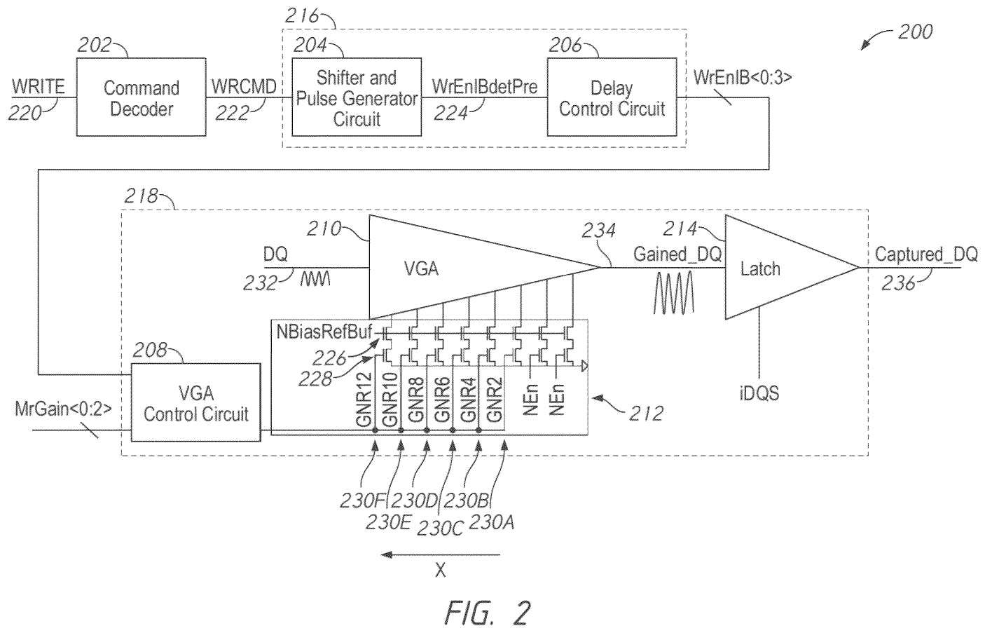

FIG. 2 illustrates an example process flow diagram for a write command according to an embodiment of the disclosure. The process flow 200 includes a command decoder 202, a shifter and pulse generator circuit 204, a delay control circuit 206, a VGA control circuit 208, a VGA 210 that includes a sink circuit 212, and a latch 214. In some embodiments of the disclosure, the shifter and pulse generator circuit 204 and the delay control circuit 206 can be implemented within a command path 216, and the VGA control circuit 208, the VGA 210 with the sink circuit 212, and the latch 214 may be implemented within an input/output circuit 218. In one embodiment, the command decoder 202 may be implemented as the command decoder 115, the command path 216 as the command path 125, and the input/output circuit 218 as the input/output circuit 160 shown in FIG. 1.

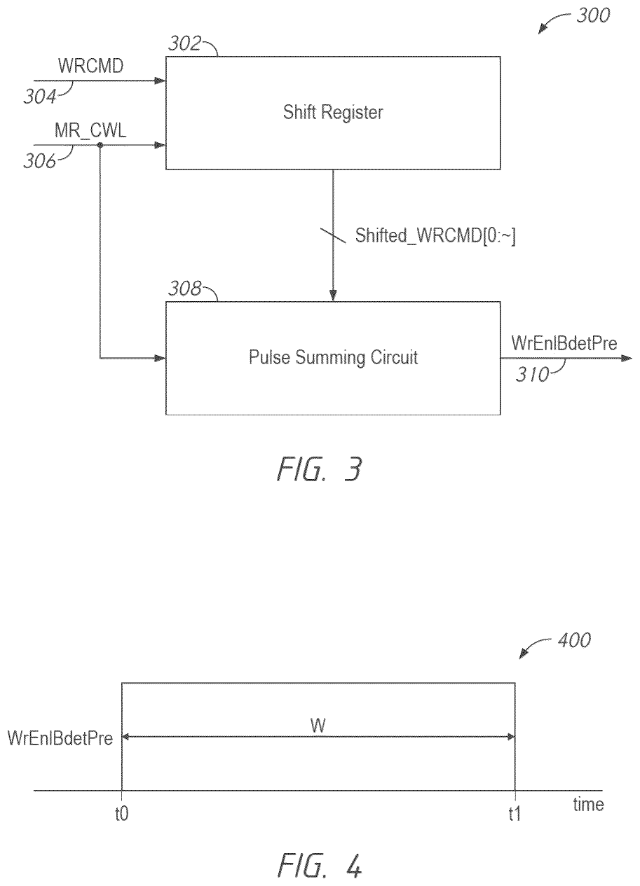

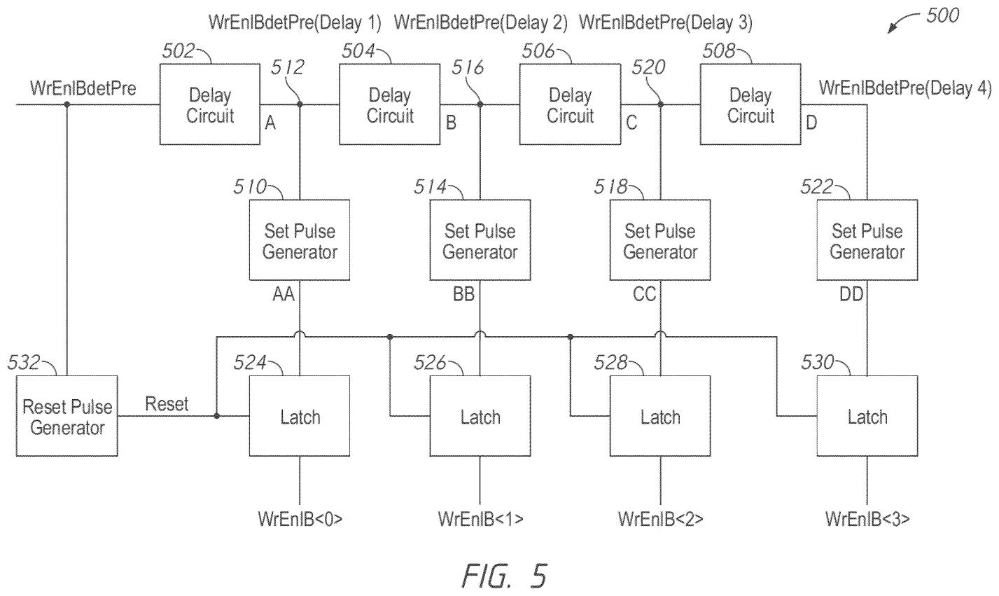

A write command WRITE is received at the command decoder 202 on signal line 220. The command decoder 202 responsively provides the WRCMD signal to the shifter and pulse generator circuit 204 on signal line 222. The shifter and pulse generator circuit 204 is configured to extend a pulse width of the WRCMD signal by a particular number of clock cycles. An example shifter and pulse generator circuit 204 is shown and described in more detail in conjunction with FIG. 3 and FIG. 4.

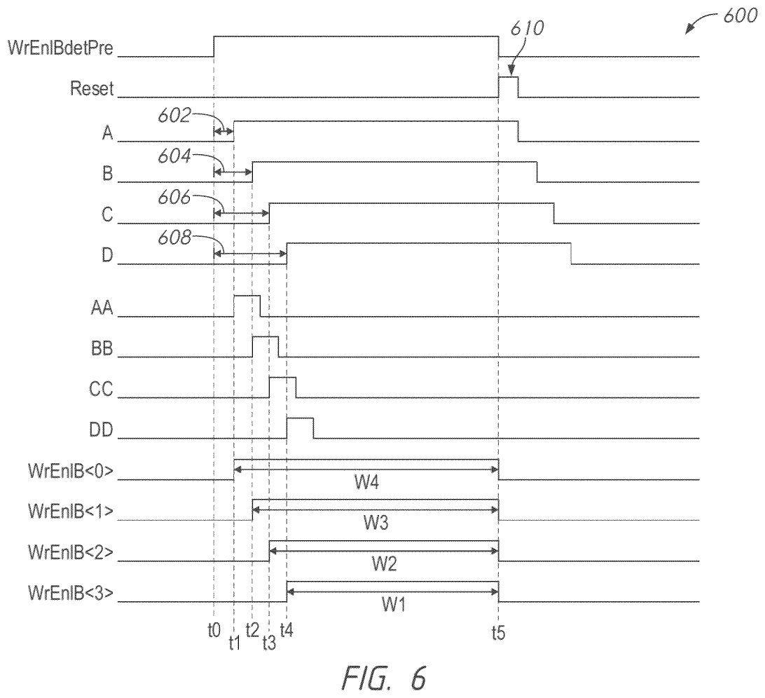

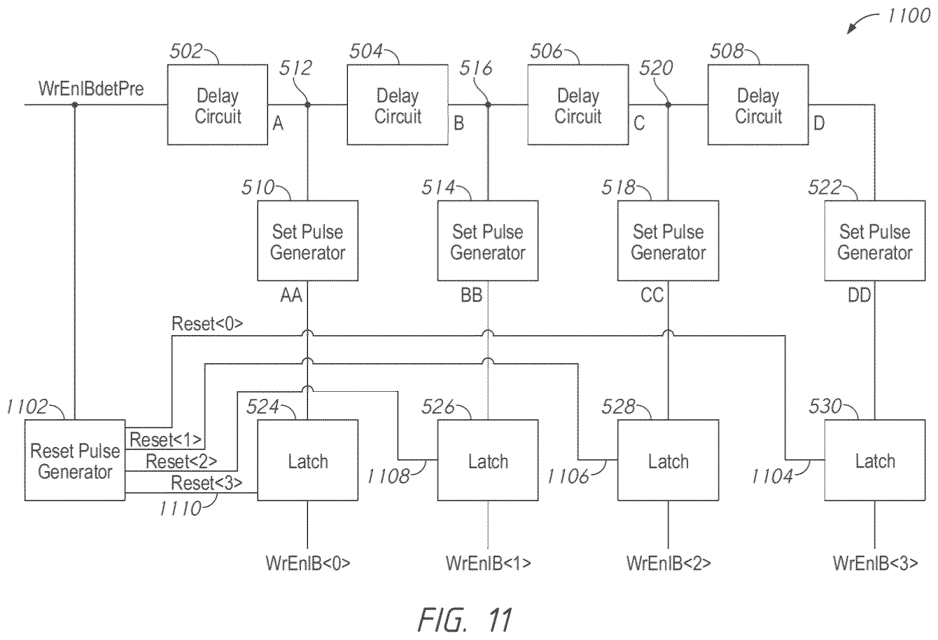

The shifter and pulse generator circuit 204 provides a pre-write enable signal WrEnIBdetPre to the delay control circuit 206 on signal line 224. The WrEnIBdetPre signal has the extended pulse width produced by the shifter and pulse generator circuit 204. The delay control circuit 206 is configured to output multiple write enable signals WrEnIB on a bus WrEnIB<0: n>. As will be described in more detail later, the WrEnIB signals are used to selectively enable sink transistors in the sink circuit 212. Each WrEnIB signal may have a staggered enable time that produces a pulse having a different pulse width compared to the other WrEnIB signals, which can reduce the power consumption of the VGA 210. An example delay control circuit 206 is shown and described in more detail in conjunction with FIG. 5 and with FIG. 11.

The WrEnIB signals on the WrEnIB<0: n> bus are received by the VGA control circuit 208. The VGA control circuit 208 also receives gain information MrGain<0: m>. Based on the WrEnIB signals and the gain information MrGain<0:2>, the VGA control circuit 208 is configured to selectively generate control signals GNR (x) to selectively enable (e.g., turn on) sink transistors in the sink circuit 212. In one embodiment, the GNR (x) signals that are provided to the sink circuit 212 have staggered enable times (which produces staggered pulses) that define an amount of time a particular sink transistor or sink transistors in the sink circuit 212 are enabled.

In the illustrated embodiment, the sink circuit 212 includes multiple sink transistors 226, 228. A sink transistor 226 is connected in series with a sink transistor 228 to produce a sink transistor pair. In the embodiment illustrated in FIG. 2, there are sink transistor pairs 230A, 230B, 230C, 230D, 230E, 230F, although other embodiments are not limited to sink transistor pairs and/or the number of sink transistor pairs. The sink transistor 228 in each sink transistor pair receives a respective GNR (x) signal at the gate of the sink transistor 228. The sink transistor 228 functions as a switch to enable or disable the sink transistor pair. The sink transistor 226 receives a reference signal NBiasRefBuf at the gate of the sink transistor 226. The NBiasRefBuf signal may be provided by a voltage generator (e.g., the voltage generator 170 of FIG. 1). When enabled, the sink transistor 226 controls the current level through the sink transistor pair.

The sink transistor pairs 230A, 230B, 230C, 230D, 230E, 230F are connected in parallel between the VGA 210 and a reference voltage (e.g., ground or VSS). In some instances, one or more of the sink transistor pairs 230A, 230B, 230C, 230D, 230E, 230F have a different drive strength. In some embodiments, each of the sink transistor pairs 230A, 230B, 230C, 230D, 230E, 230F have a different strength. For example, the sink transistor pairs 230A, 230B, 230C, 230D, 230E, 230F increase in strength as the sink transistor pairs move from right to left (e.g., the x direction in FIG. 2). Thus, the sink transistor pair 230A can be weakest sink transistor pair (e.g., the sink transistors 226, 228 in the sink transistor pair 230A have the smallest size) and the sink transistor pair 230F the strongest sink transistor pair (e.g., the sink transistors 226, 228 in the sink transistor pair 230F have the largest size). As will be described in more detail later, the VGA control circuit 208 may be configured to enable (e.g., turn on) one or more of the weakest sink transistor pairs first (e.g., sink transistor pair 230A) and the strongest sink transistor pair last (e.g., sink transistor pair 230F). In one embodiment, the VGA control circuit 208 can be configured to disable (e.g., turn off) all of the sink transistor pairs 230A, 230B, 230C, 230D, 230F at the same time. In another embodiment, the VGA control circuit 208 may be configured to disable the sink transistor pairs 230A, 230B, 230C, 230D, 230F at different times, beginning with the strongest sink transistor pair 230F and ending with the weakest sink transistor pair 230A. The sink circuit 230 can be implemented differently and/or include a different number of sink transistor pairs in other embodiments.

The VGA 210 receives write data DQ on signal line 232, amplifies the write data DQ, and provides the amplified write data Gained_DQ to the latch 214 on signal line 234. The latch 214 is configured to latch the amplified write data Gained_DQ based on the internal write clock iDQS. The latched write data Captured_DQ is output from the latch 214 on signal line 236. Thereafter, the latched write data Captured_DQ is written to a memory array via read/write amplifiers (e.g., the memory array 150 and the read/write amplifiers 155 of FIG. 1).

FIG. 3 illustrates a block diagram of an example shifter and pulse generator circuit 300 according to an embodiment of the disclosure. The shifter and pulse generator circuit 300 may be implemented in some embodiments as the shifter and pulse generator circuit 204 shown in FIG. 2. The shifter and pulse generator circuit 300 includes a shift register 302 that receives the WRCMD signal on signal line 304 and a write latency signal MR_CWL on signal line 306. MR_CWL is a delay, in clock cycles, between the WRCMD signal (internal write command signal) and the availability of the first bit of input data to be written into a memory array. The MR_CWL can be stored in a mode register (e.g., mode register 130 of FIG. 1).

In one embodiment, the shift register 302 produces multiple shifted WRCMD signals. For example, the shift register 302 may output the WRCMD signal, a WRCMD+two clock cycles (2CK) signal, a WRCMD+4CK signal, and so on up to CWL. The shifted WRCMD signals are received by a pulse summing circuit 308 via the Shifted_WRCMD [0: ˜] bus. The pulse summing circuit sums the multiple shifted WRCMD signals to produce a pre-write enable signal WrEnIBdetPre on signal line 310.

FIG. 4 illustrates an example waveform 400 of the pre-write enable signal WrEnIBdetPre of FIG. 3 according to an embodiment of the disclosure. The WrEnIBdetPre signal transitions from a first signal level (e.g., low or “0”) to a second signal level (e.g., high or “1”) at time to and transitions from the second signal level to the first signal level at a time t1. In one non-limiting nonexclusive example, the time to is the timing of a clock (e.g., a write clock WCLK) plus four clock cycles plus an “x” amount of time (i.e., WCLK+4CK+x), and the time t1 is the write latency plus eight clock cycles (CWL+8CK). The value “x” is an additional amount of time that can be used to further delay the timing of t0. The value x can adjust the delay of the enable timing of the sink transistors to reduce the enable time period of the VGA, which may further reduce the power consumption of the VGA. Thus, in FIG. 4, the pulse width W of the WrEnIBdetPre signal is between WCLK+4CK+x and CWL+8CK. The timing and the pulse width of the WrEnIBdetPre signal can differ in other embodiments.

In one embodiment, the value of x is stored in a fuse register. In an example embodiment, if x=1, the enable timing of the WrEnIBdetPre can be WCLK+5CK. In another example embodiment, if x=4, the enable timing of the WrEnIBdetPre can be WCLK+8CK.

FIG. 5 illustrates a block diagram of a first example delay control circuit 500 according to an embodiment of the disclosure. The delay control circuit 500 includes multiple delay circuits connected in series. The number of delay circuits that are connected in series may be based on the number of write enable signals WrEnIB<n> to be generated, where the number of WrEnIB<n> signals to be generated is based on the number of sink transistors to be enabled by a control signal. For example, with reference to FIG. 2, four sets of sink transistor pairs 230A, 230B, 230C, 230D, 230E, 230F may be enabled in one embodiment, where a set of sink transistor pairs includes one or two sink transistor pairs. In this example embodiment, the sink transistor pairs 230A, 230B receive one control signal (i.e., the control signals GNR2 and GNR4 are the same), and the sink transistor pairs 230C, 230D receive another control signal (i.e., the control signals GNR6 and GNR8 are the same). Thus, the one control signal GNR2/GNR4 enables two sink transistor pairs 230A, 230B at the same time, and the one control signalsGNR6/GNR8 enables two other sink transistor pairs at a different time. The control signal GNR10 is received by the sink transistor pair 230E, and the sink transistor pair 230F receives the GNR12 control signal. Thus, in FIG. 5 four WrEnIB<0>, WrEnIB<1>, WrEnIB<2>, WrEnIB<3> signals are provided by the delay control circuit 500 to enable the production of the four control signals GNR2/GNR4, GNR6/GNR8, GNR10, GNR12. In other embodiments, a different number of write enable signals and control signals may be generated.

The delay control circuit 500 of FIG. 5 includes four delay circuits 502, 504, 506, 508 connected in series. The delay circuit 502 receives the WrEnIBdetPre signal and provides a first delay to the WrEnIBdetPre signal to produce a WrEnIBdetPre (delay1) signal. A set pulse generator 510 is connected to node 512, and the set pulse generator 510 receives the WrEnIBdetPre (delay1) signal.

The delay circuit 504 receives the WrEnIBdetPre (delay1) signal and provides a second delay to the WrEnIBdetPre (delay1) signal to produce a WrEnIBdetPre (delay2) signal. A set pulse generator 514 is connected to node 516, and the set pulse generator 514 receives the WrEnIBdetPre (delay2) signal.

The delay circuit 506 receives the WrEnIBdetPre (delay2) signal and provides a third delay to the WrEnIBdetPre (delay2) signal to produce a WrEnIBdetPre (delay3) signal. A set pulse generator 518 is connected to node 520, and the set pulse generator 518 receives the WrEnIBdetPre (delay3) signal.

The delay circuit 508 receives the WrEnIBdetPre (delay3) signal and provides a fourth delay to the WrEnIBdetPre (delay3) signal to produce a WrEnIBdetPre (delay4) signal. A set pulse generator 522 is connected to the delay circuit 508 and receives the WrEnIBdetPre (delay4) signal.

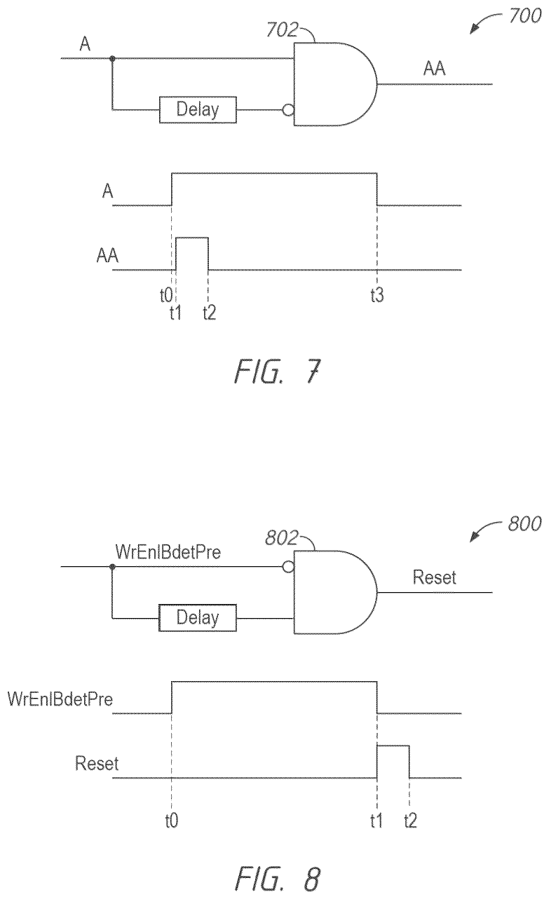

A latch circuit 524 receives the output of the set pulse generator 510 and outputs a first write enable signal WrEnIB<0>. As is described in more detail in conjunction with FIG. 6, the WrEnIB<0> signal transitions from a first signal level to a second signal level after a first delay. In one embodiment, the WrEnIB<0> signal is used to produce a control signal that enables the weakest sink transistor(s) in a sink circuit (e.g., the sink transistor pairs 230A, 230B in the sink circuit 212 of FIG. 2).

A latch circuit 526 receives the output of the set pulse generator 514 and outputs a second write enable signal WrEnIB<1>. The WrEnIB<1> signal transitions from the first signal level to the second signal level after a second delay, where the second delay is longer than the first delay. In one embodiment, the WrEnIB<1> signal is used to produce a control signal that enables a relatively weaker sink transistor(s) in a sink circuit (e.g., the sink transistor pairs 230C, 230D in the sink circuit 212 of FIG. 2).

A latch circuit 528 receives the output of the set pulse generator 518 and outputs a third write enable signal WrEnIB<2>. The WrEnIB<2> signal from the first signal level to the second signal level after a third delay, where the third delay is longer than the first delay and the second delay. In one embodiment, the WrEnIB<2> signal is used to produce a control signal that enables a relatively stronger sink transistor(s) in a sink circuit (e.g., the sink transistor pair 230E in the sink circuit 212 of FIG. 2).

A latch circuit 530 receives the output of the set pulse generator 522 and outputs a fourth write enable signal WrEnIB<3>. The WrEnIB<3> signal transitions from the first signal level to the second signal level after a fourth delay, where the fourth delay is longer than the first delay, the second delay, and the third delay. In one embodiment, the WrEnIB<3> signal is used to produce a control signal that enables the strongest sink transistor(s) in a sink circuit (e.g., the sink transistor pair 230F in the sink circuit 212 of FIG. 2).

A reset circuit 532 is configured to receive the WrEnIBdetPre signal and provide a reset signal to the latch circuits 524, 526, 528, 530. The reset signal causes the four write enable signals WrEnIB<0>, WrEnIB<1>, WrEnIB<2>, WrEnIB<3> to transition from the second signal level to the first signal level concurrently. Thus, the four write enable signals WrEnIB<0>, WrEnIB<1>, WrEnIB<2>, WrEnIB<3> have staggered enable times (i.e., transition from the first signal level to the second signal level) and concurrent disable times (i.e., transition from the second signal level to the first signal level) in the embodiment shown in FIG. 5.

FIG. 6 illustrates an example timing diagram 600 for the delay control circuit 500 shown in FIG. 5 according to an embodiment of the disclosure. At time to, the WrEnIBdetPre signal transitions from the first signal level (e.g., low or “0”) to the second signal level (e.g., high or “1”). At time t1, the signal output by the delay circuit 502 (point A), the signal output by the set pulse generator 510 (point AA), and the first WrEnIB<0> signal transition from the first signal level to the second signal level. The time period 602 includes the first delay provided by the delay circuit 502. At time t2, the signal output by the delay circuit 504 (point B), the signal output by the set pulse generator 514 (point BB), and the second WrEnIB<1> signal transition from the first signal level to the second signal level. The time period 604 includes the first delay provided by the delay circuit 502 and the second delay provided by the delay circuit 504. At time t3, the signal output by the delay circuit 506 (point C), the signal output by the set pulse generator 518 (point CC), and the third WrEnIB<2> signal transition from the first signal level to the second signal level. The time period 606 includes the first delay provided by the delay circuit 502, the second delay provided by the delay circuit 504, and the third delay provided by the delay circuit 506. At time t4, the signal output by the delay circuit 508 (point D), the signal output by the set pulse generator 522 (point DD), and the fourth WrEnIB<3> signal transition from the first signal level to the second signal level. The time period 608 includes the first delay provided by the delay circuit 502, the second delay provided by the delay circuit 504, the third delay provided by the delay circuit 506, and the fourth delay provided by the delay circuit 508.

At time t5, the WrEnIBdetPre signal transitions from the second signal level to the first signal level, which causes the reset signal to transition from the first signal level to the second signal level. The reset pulse 610 (e.g., the rising edge of the reset pulse 610) causes the four write enable signals WrEnIB<0>, WrEnIB<1>, WrEnIB<2>, WrEnIB<3> to transition from the second signal level to the first signal level.

As shown in FIG. 6, the four write enable signals WrEnIB<0>, WrEnIB<1>, WrEnIB<2>, WrEnIB<3> have staggered enable times (i.e., transition from the first signal level to the second signal level) and concurrent disable times (i.e., transition from the second signal level to the first signal level). The WrEnIB<3> signal has a pulse width W1, the WrEnIB<2> signal has a pulse width W2, the WrEnIB<1> signal has a pulse width W3, and the WrEnIB<0> signal has a pulse width W4. W1 is less than W2, W2 is less than W3, and W3 is less than W4 (W1<W2<W3<W4).

The timing diagram of FIG. 6 is an example timing diagram that is based on the first example delay control circuit 500 shown in FIG. 5 and the example process flow 200 shown in FIG. 2. Other embodiments are not limited to the implementations shown in FIGS. 2, 5, and 6. For example, the sink circuit 212 can include a different number of sink transistors and/or sink transistor pairs 230A, 230B, 230C, 230D, 230E, 230F. Additionally or alternatively, different sets of sink transistor pairs in the sink circuit 212 can be enabled and disabled. For example, each sink transistor pair 230A, 230B, 230C, 230D, 230E, 230F can be enabled individually. Those skilled in the art will recognize that enabling each sink transistor pair 230A, 230B, 230C, 230D, 230E, 230F individually can involve a different number of WrEnIB<n> signals.

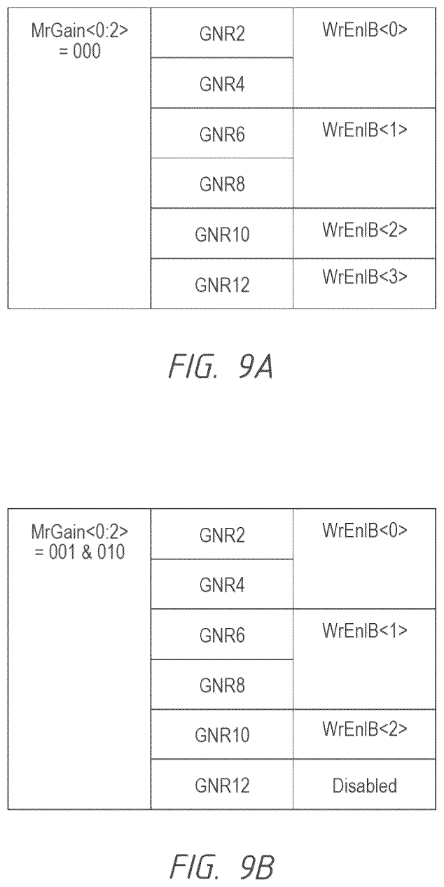

FIG. 7 illustrates a block diagram of an example set pulse generator 700 with example waveform diagrams according to an embodiment of the disclosure. FIG. 7 is described in conjunction with FIG. 5. In particular, FIG. 7 is described in conjunction with the delay circuit 502 and as such, the set pulse generator 700 is the set pulse generator 510 shown in FIG. 5. The other set pulse generators 514, 518, 522 may also be implemented as the set pulse generator 700 in some embodiments.

The set pulse generator 700 includes an AND gate 702 that receives the signal output by the delay circuit 502 (point A) and a delayed signal (active low) 704 as inputs. The output of the AND gate 702 is the signal at point AA. The signal at point A transitions from the first signal level (e.g., low or “0”) to the second signal level (high or “1”) at time t0 and transitions from the second signal level to the first signal level at time t3. The signal at point AA transitions from the first signal level to the second signal level at time t1 and transitions from the second signal level to the first signal level at time t2.

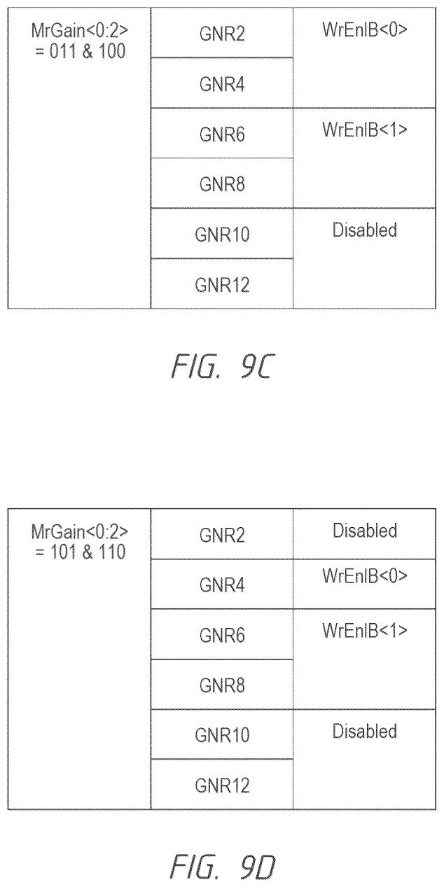

FIG. 8 illustrates a block diagram of an example reset pulse generator 800 with example waveform diagrams according to an embodiment of the disclosure according to an embodiment of the disclosure. FIG. 8 is described in conjunction with FIG. 5. The reset pulse generator 800 includes an AND gate 802 that receives the WrEnIBdetPre signal (active low) and a delayed WrEnIBdetPre signal as inputs. The output of the AND gate 802 is the Reset signal. The WrEnIBdetPre signal transitions from the first signal level (e.g., low or “0”) to the second signal level (high or “1”) at time to and transitions from the second signal level to the first signal level at time t2. The Reset signal transitions from the first signal level to the second signal level at time t1 and transitions from the second signal level to the first signal level at time t2.

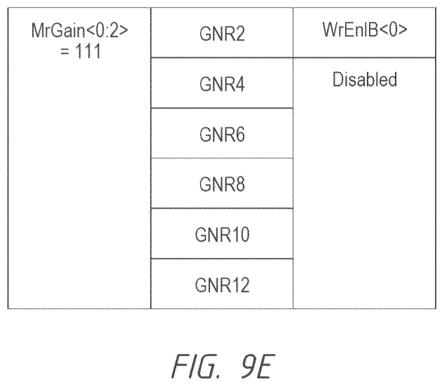

FIGS. 9A-9E illustrate example operations of a VGA control circuit according to an embodiment of the disclosure according to an embodiment of the disclosure. The VGA control circuit may be implemented as the VGA control circuit 208 shown in FIG. 2 in some embodiments. As shown in FIG. 2, the VGA control circuit receives the WrEnIB<n> signals on the WrEnIB<0:3> bus and the gain information MrGain<0:2>. The VGA control circuit is configured to decode the WrEnIB signals and the gain information MrGain<0:2> to provide the GNRx signals. In the example embodiment shown in FIG. 2, the gain information MrGain<0:2> is comprised of three bits. Other embodiments are not limited to this implementation.

FIG. 9A illustrates an example operation of the VGA control circuit when the gain information MrGain<0:2> is zero (000). The GNR2 signal and the GNR4 signal are provided as having the same timing as the WrEnIB<0> signal. The GNR6 signal and the GNR8 signal are provided as having the same timing as the WrEnIB<1> signal. The GNR10 signal is provided as having the same timing as the WrEnIB<2> signal. The GNR12 signal is provided as having the same timing as the WrEnIB<3> signal. In this example operation, the sink transistor pairs 230A and 230B, the sink transistor pairs 230C and 230D, the sink transistor pair 230E, and the sink transistor pair 230F in the sink circuit 212 of FIG. 2 are enabled at staggered times.

FIG. 9B illustrates an example operation of the VGA control circuit when the gain information MrGain<0:2> is one (001) and two (010). The GNR2 signal and the GNR4 signal are provided as having the same timing as the WrEnIB<0> signal. The GNR6 signal and the GNR8 signal are provided as having the same timing as the WrEnIB<1> signal. The GNR 10 signal is provided as having the same timing as the WrEnIB<2> signal. The GNR12 signal is disabled. In this example operation, the sink transistor pairs 230A and 230B, the sink transistor pairs 230C and 230D, and the sink transistor pair 230E in the sink circuit 212 are enabled at staggered times. The sink transistor pair 230F is disabled (e.g., not turned on).

FIG. 9C illustrates an example operation of the VGA control circuit when the gain information MrGain<0:2> is three (011) and four (100). The GNR2 signal and the GNR4 signal are provided as having the same timing as the WrEnIB<0> signal. The GNR6 signal and the GNR8 signal are provided as having the same timing as the WrEnIB<1> signal. The GNR10 signal and the GN12 signal are disabled. In this example operation, the sink transistor pairs 230A and 230B and the sink transistor pairs 230C and 230D in the sink circuit 212 are enabled at staggered times. The sink transistor pairs 230E, 230F are disabled.

FIG. 9D illustrates an example operation of the VGA control circuit when the gain information MrGain<0:2> is five (101) and six (110). The GNR4 signal is provided as having the same timing as the WrEnIB<0> signal. The GNR6 signal and the GNR8 signal are provided as having the same timing as the WrEnIB<1> signal. The GNR2 signal, the GNR10 signal, and the GN12 signal are disabled. In this example operation, the sink transistor pair 230B, the sink transistor pair 230C, and the sink transistor pair 230D in the sink circuit 212 are enabled at staggered times. The sink transistor pairs 230A, 230E, 230F are disabled (e.g., not turned on).

FIG. 9E illustrates an example operation of the VGA control circuit when the gain information MrGain<0:2> is seven (111). The GNR2 signal is provided as having the same timing as the WrEnIB<0> signal. The GNR4 signal, the GNR6 signal, the GNR8 signal, the GNR10 signal, and the GN12 signal are disabled. In this example operation, the sink transistor pair 230A in the sink circuit 212 is enabled. The sink transistor pair 230B, the sink transistor pair 230C, the sink transistor pair 230D, the sink transistor pair 230E, and the sink transistor pair 230F are disabled.

As shown in FIGS. 9A-9E, the gain information MrGain<0:2> can be used to selectively enable sink transistors in a sink circuit. Thus, a VGA control circuit can be configured to selectively enable sink transistors in a sink circuit. The gain information MrGain<0:2> can be used to determine which write enable signals WrEnIB are enabled (e.g., output by the VGA control circuit) and which write enable signals WrEnIB are disabled (e.g., not output by the VGA control circuit).

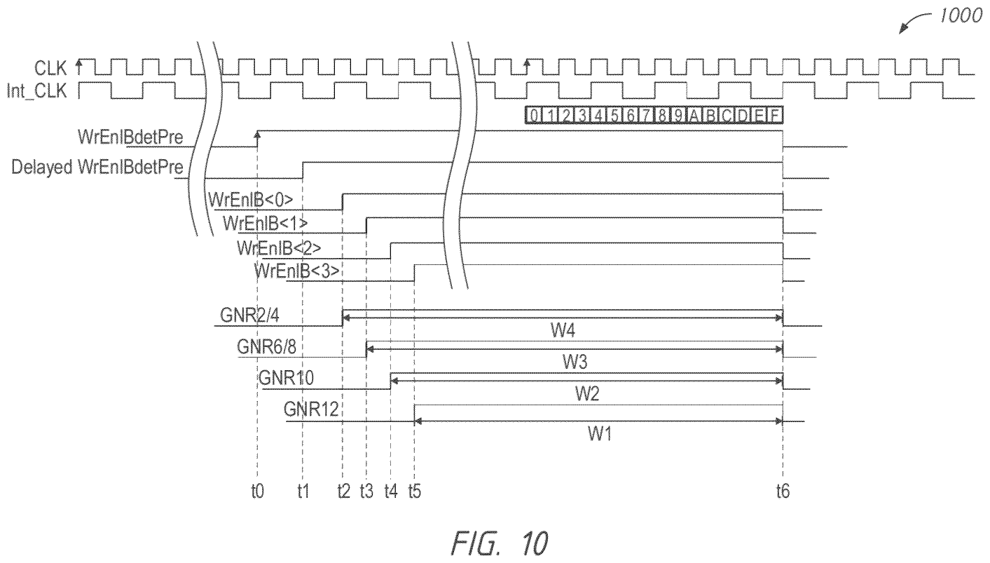

FIG. 10 illustrates a first example timing diagram 1000 for a variable gain amplifier power savings according to an embodiment of the disclosure. The WRITE command is provided to the command decoder, and the command decoder responsively provides the WRCMD signal (not shown in FIG. 10). At time to, the WrEnIBdetPre signal transitions from the first signal level (e.g., low or “0”) to the second signal level (high or “1”). At time t1, a delayed WrEnIBdetPre signal transitions from the first signal level to the second signal level. At time t2, the WrEnIB<0> signal, the control signal GNR2, and the control signal GNR4 transition from the first signal level to the second signal level. The sink transistor(s) in a sink circuit that receive the control signal GNR2 and the control signal GNR4 are enabled (e.g., turned on). For example, with reference to FIG. 2, the sink transistor pairs 230A, 230B are enabled.

At time t3, the WrEnIB<1> signal, the control signal GNR6, and the control signal GNR8 transition from the first signal level to the second signal level. The sink transistor(s) in a sink circuit that receive the GNR6 signal and the GNR8 signal are enabled. For example, with reference to FIG. 2, the sink transistor pairs 230C, 230D are enabled.

At time t4, the WrEnIB<2> signal and the control signal GNR10 transition from the first signal level to the second signal level. The sink transistor(s) in a sink circuit that receives the GNR10 signal is enabled. For example, with reference to FIG. 2, the sink transistor pair 230E is enabled.

At time t5, the WrEnIB<3> signal and the control signal GNR12 transition from the first signal level to the second signal level. The sink transistor(s) in a sink circuit that receives the GNR12 signal is enabled. For example, with reference to FIG. 2, the sink transistor pair 230F is enabled.

At time t6, the WrEnIBdetPre signal transitions from the second signal level to the first signal level, which causes the GNR2 signal, the GNR4 signal, the GNR6 signal, the GNR8 signal, the GNR10 signal, and the GNR12 signal to transition from the second signal level to the first signal level. The transitions in the GNR2 signal, the GNR4 signal, the GNR6 signal, the GNR8 signal, the GNR10 signal, and the GNR12 signal cause all of the sink transistors in a sink circuit to be disabled (e.g., turned off). For example, with reference to FIG. 2, the sink transistor pairs 230A, 230B, 230C, 230D, 230E, and 230F are disabled.

As shown in FIG. 10, the timing of the control signals GNR2, GNR4, GNR6, GNR8, GNR10, and GNR 12 correspond to respective write enable signals WrEnIB<0>, WrEnIB<1>, WrEnIB<2>, WrEnIB<3>. The enable and disable times of the GNR2 and the GNR4 signals correspond to the enable and disable times of the WrEnIB<0> signal. The enable and disable times of the GNR6 and the GNR8 signals correspond to the enable and disable times of the WrEnIB<1> signal. The enable and disable times of the GNR10 signal correspond to the enable and disable times of the WrEnIB<2> signal. The enable and disable times of the GNR12 signal correspond to the enable and disable times of the WrEnIB<3> signal.

Additionally, the control signals GNR2/GNR4, GNR6/GNR8, GNR10, and GNR 12 have different pulse widths. The control signal GNR2/GNR4 has a pulse width W4. The control signal GNR6/GNR8 has a pulse width W3. The control signal GNR10 has a pulse width W2. The control signal GNR 12 has a pulse width W1. The pulse width W1 is less than the pulse width W2, the pulse width W2 is less than the pulse width W3, and the pulse width W3 is less than the pulse width W4 (W1<W2<W3<W4). Thus, the different pulse widths can be used to reduce or minimize the amount of time the sink transistors are enabled. For example, the strongest sink transistor(s) may be enabled by the GNR 12 signal, which has the shortest pulse width, while the weakest sink transistor(s) can be enabled by the GNR2/GNR4 signal, which has the longest pulse width. In this manner, the power consumption of the VGA can be further reduced.

FIG. 11 illustrates a block diagram of a second example delay control circuit 1100 according to an embodiment of the disclosure. The delay control circuit 1100 is similar to the delay control circuit 500 shown in FIG. 5 (see same reference numbers), with the exception of the reset pulse generator 1102. For brevity, only the reset pulse generator 1102 is described.

The reset pulse generator 1102 is configured to produce multiple reset signals Reset<m>. In the illustrated embodiment, the reset pulse generator 1102 provides four Reset signals Reset<0>, Reset<1, Reset<2>, Reset<3>. The latch 530 receives the Reset<0> signal on signal line 1104. The Reset<0> signal determines a pulse width of the WrEnIB<3> signal. The enable time of the WrEnIB<3> signal (e.g., transition from the first signal level (low or “0”) to the second signal level (high or “1”)) is based on the WrEnIBdetPre signal and the disable time of the WrEnIB<3> signal (e.g., transition from the second signal level to the first signal level) is based on the Reset<0> signal.

The latch 528 receives the Reset<1> signal on signal line 1106. The Reset<1> signal determines a pulse width of the WrEnIB<2> signal. The enable time of the WrEnIB<2> signal is based on the WrEnIBdetPre signal and the disable time of the WrEnIB<2> signal is based on the Reset<1> signal. The latch 526 receives the Reset<2> signal on signal line 1108. The Reset<2> signal determines a pulse width of the WrEnIB<1> signal. The enable time of the WrEnIB<1> signal is based on the WrEnIBdetPre signal and the disable time of the WrEnIB<1> signal is based on the Reset<2> signal. The latch 524 receives the Reset<3> signal on signal line 1110. The Reset<3> signal determines a pulse width of the WrEnIB<0> signal. The enable time of the WrEnIB<0> signal is based on the WrEnIBdetPre signal and the disable time of the WrEnIB<0> signal is based on the Reset<3> signal. Based on the timing of the Reset<3> signal, the Reset<2> signal, the Reset<1> signal, and the Reset<0> signal, the WrEnIB<0>, WrEnIB<1>, WrEnIB<2>, and WrEnIB<3> signals, respectively, can each have a different pulse width with different staggered enable times and different staggered disable times.

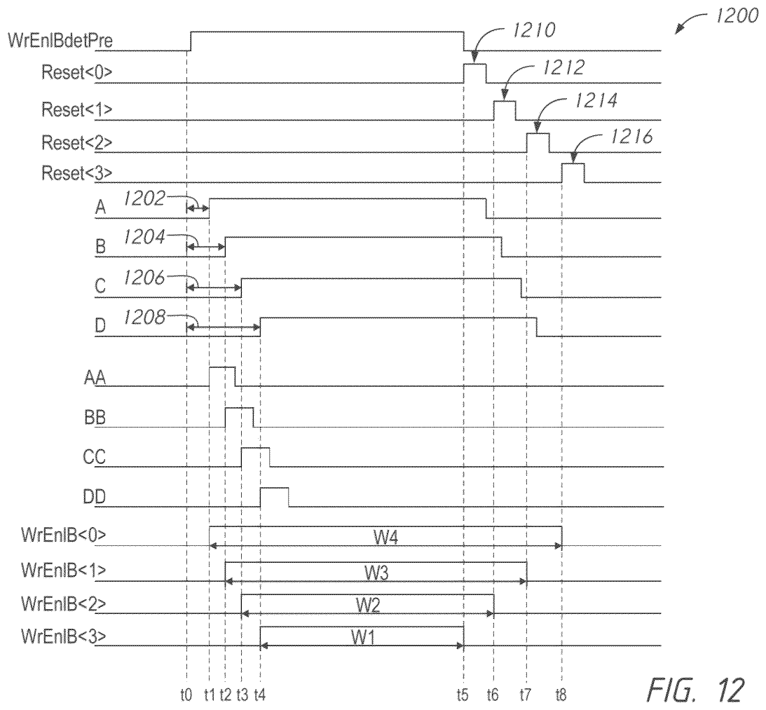

FIG. 12 illustrates an example timing diagram 1200 for the delay control circuit 1100 shown in FIG. 11 according to an embodiment of the disclosure. At time to, the WrEnIBdetPre signal transitions from the first signal level (e.g., low or “0”) to the second signal level (e.g., high or “1”). At time t1, the signal output by the delay circuit 502 (point A), the signal output by the set pulse generator 510 (point AA), and the first WrEnIB<0> signal transition from the first signal level to the second signal level. The time period 1202 includes the first delay provided by the delay circuit 502.

At time t2, the signal output by the delay circuit 504 (point B), the signal output by the set pulse generator 514 (point BB), and the second WrEnIB<1> signal transition from the first signal level to the second signal level. The time period 1204 includes the first delay provided by the delay circuit 502 and the second delay provided by the delay circuit 504. At time t3, the signal output by the delay circuit 506 (point C), the signal output by the set pulse generator 518 (point CC), and the third WrEnIB<2> signal transition from the first signal level to the second signal level. The time period 1206 includes the first delay provided by the delay circuit 502, the second delay provided by the delay circuit 504, and the third delay provided by the delay circuit 506.

At time t4, the signal output by the delay circuit 508 (point D), the signal output by the set pulse generator 522 (point DD), and the fourth WrEnIB<3> signal transition from the first signal level to the second signal level. The time period 1208 includes the first delay provided by the delay circuit 502, the second delay provided by the delay circuit 504, the third delay provided by the delay circuit 506, and the fourth delay provided by the delay circuit 508.

At time t5, the WrEnIBdetPre signal transitions from the second signal level to the first signal level, which causes the Reset<0> signal to transition from the first signal level to the second signal level. The reset pulse 1210 (e.g., the rising edge of the reset pulse 1210) causes the fourth WrEnIB<3> signal to transition from the second signal level to the first signal level. At time t6, the Reset<1> signal transitions from the first signal level to the second signal level. The reset pulse 1212 (e.g., the rising edge of the reset pulse 1212) causes the third WrEnIB<2> signal to transition from the second signal level to the first signal level.

At time t7, the Reset<2> signal transitions from the first signal level to the second signal level. The reset pulse 1214 (e.g., the rising edge of the reset pulse 1214) causes the second WrEnIB<1> signal to transition from the second signal level to the first signal level. At time t8, the Reset<3> signal transitions from the first signal level to the second signal level. The reset pulse 1216 (e.g., the rising edge of the reset pulse 1216) causes the first WrEnIB<0> signal to transition from the second signal level to the first signal level.

As shown in FIG. 12, the four write enable signals WrEnIB<0>, WrEnIB<1>, WrEnIB<2>, WrEnIB<3> have staggered enable times (i.e., t1, t2, t3, t4, respectively) and staggered disable times (i.e., t8, t7, t6, t5, respectively). The WrEnIB<3> signal has a pulse width W1, the WrEnIB<2> signal has a pulse width W2, the WrEnIB<1> signal has a pulse width W3, and the WrEnIB<0> signal has a pulse width W4. W1 is less than W2, W2 is less than W3, and W3 is less than W4 (W1<W2<W3<W4).

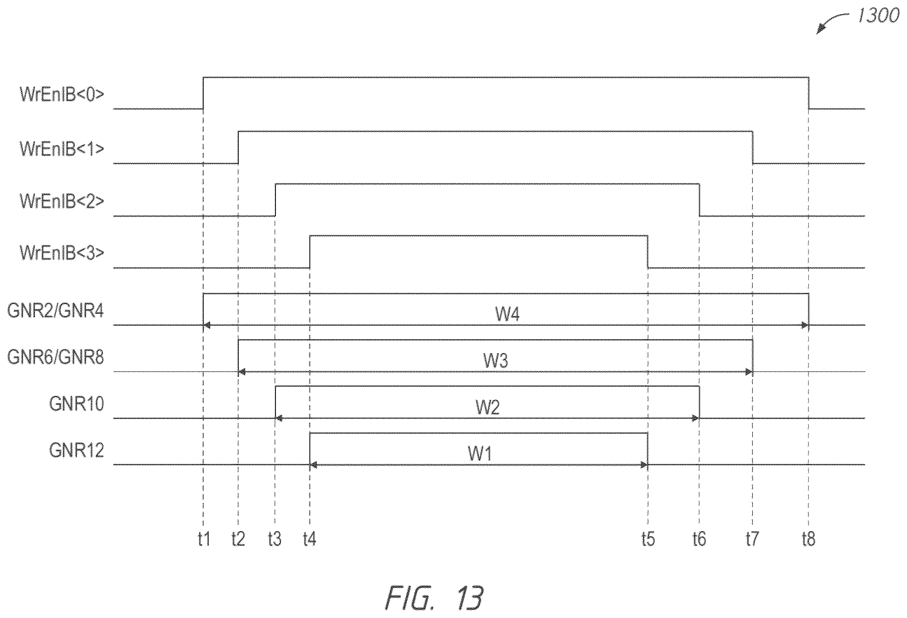

FIG. 13 illustrates a second example timing diagram 1300 for a variable gain amplifier power savings according to an embodiment of the disclosure. The timing diagram 1300 is for the delay control circuit shown in FIG. 11 and depicts the WrEnIB<n> signals and the GNRx signals. The WrEnIB<n> signals and the GNRx signals have staggered enable times and staggered disable times.

At time t1, the WrEnIB<0> signal, the GNR2 signal, and the GNR4 signal transition from the first signal level (e.g., low or “0”) to the second signal level (e.g., high or “1”). In the embodiment shown in FIG. 2, the transition in the GNR2 signal enables the sink transistor pair 230A and the transition in the GNR4 signal enables the sink transistor pair 230B.

At time t2, the WrEnIB<1> signal, the GNR6 signal, and the GNR8 signal transition from the first signal level to the second signal level. In the embodiment shown in FIG. 2, the transition in the GNR6 signal enables the sink transistor pair 230C and the transition in the GNR8 signal enables the sink transistor pair 230D. At time t3, the WrEnIB<2> signal and the GNR 10 signal transition from the first signal level to the second signal level. In the embodiment shown in FIG. 2, the transition in the GNR 10 signal enables the sink transistor pair 230E. At time t4, the WrEnIB<3> signal and the GNR12 signal transition from the first signal level to the second signal level. In the embodiment shown in FIG. 2, the transition in the GNR12 signal enables the sink transistor pair 230F.

At time t5, the WrEnIB<3> signal and the GNR12 signal transition from the second signal level to the first signal level. The GNR12 signal has the same enable and disable times (i.e., the same timing) as the WrEnIB<3> signal. In the embodiment shown in FIG. 2, the transition in the GNR12 signal disables the sink transistor pair 230F.

At time t6, the WrEnIB<2> signal and the GNR10 signal transition from the second signal level to the first signal level. The GNR10 signal has the same enable and disable times (i.e., the same timing) as the WrEnIB<2> signal. In the embodiment shown in FIG. 2, the transition in the GNR10 signal disables the sink transistor pair 230E.

At time t7, the WrEnIB<1> signal, the GNR8 signal, and the GNR6 signal transition from the second signal level to the first signal level. The GNR6 signal and the GNR8 signal have the same enable and disable times (i.e., the same timing) as the WrEnIB<1> signal. In the embodiment shown in FIG. 2, the transitions in the GNR6 and the GNR8 signals disable the sink transistor pairs 230C, 230D, respectively.

At time t8, the WrEnIB<0> signal, the GNR4 signal, and the GNR2 signal transition from the second signal level to the first signal level. The GNR4 signal and the GNR2 signal have the same enable and disable times (i.e., the same timing) as the WrEnIB<0> signal. In the embodiment shown in FIG. 2, the transitions in the GNR2 and the GNR4 signals disable the sink transistor pairs 230A, 230B, respectively.

As shown in FIG. 13, the timing of the control signals GNR2, GNR4, GNR6, GNR8, GNR10, and GNR 12 correspond to respective write enable signals WrEnIB<0>, WrEnIB<1>, WrEnIB<2>, WrEnIB<3>. The enable and disable times of the GNR2 and the GNR4 signals correspond to the enable and disable times of the WrEnIB<0> signal. The enable and disable times of the GNR6 and the GNR8 signals correspond to the enable and disable times of the WrEnIB<1> signal. The enable and disable times of the GNR10 signal corresponds to the enable and disable times of the WrEnIB<2> signal. The enable and disable times of the GNR12 signal corresponds to the enable and disable times of the WrEnIB<3> signal.

Additionally, the control signals GNR2/GNR4, GNR6/GNR8, GNR10, and GNR 12 have different pulse widths. The control signal GNR2/GNR4 has a pulse width W4. The control signal GNR6/GNR8 has a pulse width W3. The control signal GNR10 has a pulse width W2. The control signal GNR 12 has a pulse width W1. The pulse width W1 is less than the pulse width W2, the pulse width W2 is less than the pulse width W3, and the pulse width W3 is less than the pulse width W4 (W1<W2<W3<W4). Thus, the different pulse widths can be used to reduce or minimize the amount of time the sink transistors are enabled. For example, the strongest sink transistor(s) may be enabled by the GNR 12 signal, which has the shortest pulse width, while the weakest sink transistor(s) can be enabled by the GNR2/GNR4 signal, which has the longest pulse width. In this manner, the power consumption of the VGA can be further reduced. Additionally, the staggered disable times may reduce or limit power fluctuations in a memory device.

The timing diagrams of FIG. 12 and FIG. 13 are example timing diagrams that are based on the second example delay control circuit 1100 shown in FIG. 11, and the example process flow shown in FIG. 2. Other embodiments are not limited to the implementations shown in FIGS. 2, 11, 12 and 13. For example, the sink circuit 212 can include a different number of sink transistor pairs 230A, 230B, 230C, 230D, 230E, 230F. Additionally or alternatively, different sets of sink transistor pairs in the sink circuit 212 can be enabled and disabled. For example, each sink transistor pair 230A, 230B, 230C, 230D, 230E, 230F can be enabled individually. Those skilled in the art will recognize that enabling each sink transistor pair 230A, 230B, 230C, 230D, 230E, 230F individually would include a different number of WrEnIB<n> signals and possibly Reset<m> signals.

The foregoing description, for purposes of explanation, uses specific nomenclature to provide a thorough understanding of the described embodiments. However, it will be apparent to one skilled in the art that the specific details are not required to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. An apparatus, comprising:
a variable gain amplifier (VGA) comprising a sink circuit, the sink circuit comprising a first sink transistor and a second sink transistor; and
a VGA control circuit configured to provide control signals to the sink circuit to selectively enable at least one of the first sink transistor or the second sink transistor in the sink circuit.

2. The apparatus of claim 1, further comprising a mode register configured to store gain information.

3. The apparatus of claim 2, wherein:
the VGA control circuit is configured to receive the gain information; and
the control signals are based on the gain information.

4. The apparatus of claim 1, further comprising a command path configured to receive an internal write command signal and provide enable signals to the VGA control circuit, wherein the control signals are based on the enable signals.

5. The apparatus of claim 4, wherein the command path comprises:
a shifter and pulse generator circuit configured to receive the internal write command signal; and
a delay control circuit configured to receive a summed signal from the shifter and pulse generator circuit and provide the enable signals.

6. The apparatus of claim 5, wherein the shifter and pulse generator circuit comprises:
a shift register configured to output shifted signals, each shifted signal shifted by a different amount of time; and
a pulse summing circuit configured to receive and sum the shifted signals to provide the summed signal.

7. The apparatus of claim 6, wherein the delay control circuit comprises for each control signal:
a delay circuit;
a set pulse generator circuit connected to an output of the delay circuit; and
a latch connected to an output of the set pulse generator and configured to provide a respective enable signal.

8. The apparatus of claim 4, further comprising a command decoder configured to provide the internal write signal to the command path.

9. The apparatus of claim 1, wherein the VGA control circuit is further configured to:
enable the first sink transistor at a first time;
enable the second sink transistor at a second time, the second time later than the first time; and
disable the first sink transistor and the second sink transistor at a third time, the third time later than the second time.

10. The apparatus of claim 1, wherein the VGA control circuit is further configured to:
enable the first sink transistor at a first time;
enable the second sink transistor at a second time, the second time later than the first time;
disable the second sink transistor at a third time; and
disable the first sink transistor at a fourth time, the fourth time later than the third time.

11. A memory device, comprising:
a mode register configured to store gain information; and
an input/output circuit comprising:
a variable gain amplifier (VGA) comprising a sink circuit, the sink circuit comprising a first sink transistor and a second sink transistor; and
a VGA control circuit configured enable the first sink transistor at a first time and the second sink transistor at a second time based on the gain information, wherein the second time is later than the first time.

12. The memory device of claim 11, wherein the VGA control circuit is further configured to disable the first sink transistor and the second sink transistor at a third time, the third time later than the second time.

13. The memory device of claim 11, wherein the VGA control circuit is further configured to:
disable the second sink transistor at a third time; and
disable the first sink transistor at a fourth time, the fourth time later than the third time.

14. The memory device of claim 11, further comprising a memory array, the input/output circuit configured to receive write data to be written to the memory array.

15. The memory device of claim 14, further comprising:
a command decoder configured to provide an internal write signal based on receipt of a write command; and
a command path configured to receive the internal write command signal and provide enable signals to the VGA control circuit, wherein the first sink transistor and the second sink transistor are enabled based on the enable signals.

16. The memory device of claim 15, wherein the command path comprises:
a shifter and pulse generator circuit configured to receive the internal write command signal; and
a delay control circuit configured to receive a summed signal from the shifter and pulse generator circuit and provide the control signals.

17. The memory device of claim 16, wherein the shifter and pulse generator circuit comprises:
a shift register configured to output shifted signals, each shifted signal shifted by a different amount of time; and
a pulse summing circuit configured to receive and sum the shifted signals to provide the summed signal.

18. The memory device of claim 16, wherein the delay control circuit comprises for each control signal:
a delay circuit;
a set pulse generator circuit connected to an output of the delay circuit; and
a latch connected to an output of the set pulse generator circuit and configured to provide a respective enable signal.

19. The memory device of claim 11, wherein the input/output circuit further comprises a latch connected to an output of the VGA.

20. A memory device, comprising:
a memory array;
a mode register configured to store gain information; and
an input/output circuit configured to receive write data to be written to the memory array, the input/output circuit comprising:
a variable gain amplifier (VGA) comprising a first sink transistor and a second sink transistor; and
a VGA control circuit configured to receive the gain information and enable signals and responsively provide a first control signal having a first pulse width to the first sink transistor and a second control signal having a second pulse width to the second sink transistor, wherein the first pulse width differs from the second pulse width.

21. The memory device of claim 20, wherein the first control signal and the second control signal disable the first sink transistor and the second sink transistor at one time.

22. The memory device of claim 20, wherein the first control signal and the second control signal disable the first sink transistor and the second sink transistor, respectively, at different times.

23. The memory device of claim 20, further comprising:
a command decoder configured to provide an internal write signal based on receipt of a write command; and
a command path configured to receive the internal write command signal and provide the enable signals to the VGA control circuit.

24. The memory device of claim 20, wherein the input/output circuit further comprises a latch connected to an output of the VGA.

25. The memory device of claim 20, wherein the memory device is included in a dual in-line memory module.

26. A method, comprising:
receiving gain information and enable signals;
based on the gain information and the enable signals, providing a first control signal to a sink circuit of a variable gain amplifier, the first control signal enabling a first sink transistor in the sink circuit at a first time; and
based on the gain information and the enable signals, providing a second control signal to the sink circuit of the variable gain amplifier, the second control signal enabling a second sink transistor in the sink circuit at a second time, wherein the second time is later than the first time.

27. The method of claim 26, further comprising:
disabling the first sink transistor at a third time based on the first control signal; and
disabling the second sink transistor at the third time based on the second control signal, wherein the third time is later than the second time.

28. The method of claim 26, further comprising:
disabling the second sink transistor at a third time based on the second control signal; and
disabling the first sink transistor at a fourth time based on the first control signal, wherein the third time is later than the second time and the fourth time is later than the third time.

29. The method of claim 26, wherein the gain information and the enable signals are received in response to a write command received at a memory device.
